(19) United States
(12) Patent Application Publication
(10) Pub. No.: US 2026/0291533 A1
(43) Pub. Date: Sep. 24, 2026

(54) ALTERNATIVE DIPLEXER-BASED ACOUSTIC UNWANTED SPURS AND LOSSES REDUCTION TECHNIQUE

(71) Applicant: Qorvo US, Inc., Greensboro, NC (US)

(72) Inventor: Chris Levesque, Fountain Valley, CA (US)

(21) Appl. No.: 19/443,105

(22) Filed: Jan. 8, 2026

Related U.S. Application Data
(60) Provisional application No. 63/806,264, filed on May 15, 2025.
(60) Provisional application No. 63/773,746, filed on Mar. 18, 2025.

(51) Int. Cl. H04B 1/04; H03H 9/54; H03H 9/64

(52) U.S. Cl. CPC H04B 1/0483; H03H 9/54; H03H 9/64

(57) ABSTRACT

Radio frequency (RF) circuits and method of operating the same are disclosed. In some embodiments, the RF circuit includes an input terminal and an output terminal. A first filter path is connected between the input terminal and the output terminal, wherein the first filter path includes an acoustic filter. The second filter path with a second RF filter is connected between the input terminal and the output terminal, wherein the second filter path includes a second filter. The acoustic filter provides a notch and a first type of filter response that filters out spurious modes. The second RF filter has a second type of filter response that is opposite the first type of frequency response of the acoustic filter. The second filter path thus provides a bypass path to allow portions of the signal in the same frequency range as the spurious modes to pass to the output terminal.

### RELATED APPLICATIONS

This application claims the benefit of provisional patent application serial number 63/806,264, filed May 15, 2025, and provisional patent application serial number 63/773,746, filed March 18, 2025, the disclosures of which are hereby incorporated herein by reference in their entireties.

This application is also related to U.S. Patent Application serial number 19/241,608, filed June 18, 2025, which claims the benefit of provisional patent application serial number 63/661,967, filed June 20, 2024, the disclosures of which are hereby incorporated herein by reference in their entireties.

### FIELD OF THE DISCLOSURE

This disclosure relates generally to radio frequency filters that utilize acoustic filters and methods of operating the same.

### BACKGROUND

Acoustic filters are utilized in front-end radio frequency (RF) modules to isolate desired signals while rejecting unwanted interference, noise, and adjacent channel signals. Utilizing the piezoelectric effect, acoustic filters can precisely manipulate acoustic waves to achieve high selectivity and low insertion losses, thereby maximizing key metrics for optimizing signal quality. Whether it is in cellular networks, Wi-Fi, or Bluetooth connections, acoustic filters help ensure reliable and efficient communication by maintaining signal integrity and minimizing interference, ultimately enhancing the overall performance of RF modules in modern wireless devices.

Acoustic filters can be utilized to provide notches in the frequency spectrum. Acoustic filters that have a notch are designed to deliver precise rejection capabilities, attenuating a specific value in decibels across a defined frequency spectrum. The frequencies that fall outside the notch’s frequency range remain unaffected, ensuring minimal signal loss. The sharpness of the notch is a critical feature, necessitating a high quality (Q) factor, which is a hallmark of acoustic technologies. Despite their advantages, acoustic technologies are not without their drawbacks, as they can produce undesirable spurious responses and inherent bulk losses, particularly around the resonant frequencies. These unwanted anomalies can lead to significant amplitude fluctuations and increased insertion losses within the passbands.

### SUMMARY

Embodiment 1. A radio frequency (RF) circuit, includes: an input terminal; an output terminal; a first filter path connected between the input terminal and the output terminal, wherein the first filter path includes an acoustic filter that defines a notch and a first filter response, wherein the first filter response is a first type of filter response; a second filter path connected between the input terminal and the output terminal, wherein the second filter path includes a second filter that is at least one of a lumped element filter and a printed element filter, wherein second filter defines a second type of filter response; wherein the first type of filter response is one of either a low pass response or a high pass response; and wherein the second type of filter response is of another one of the low pass type filter response or the high pass type filter response.

Embodiment 2. The RF circuit of embodiment 1, wherein another acoustic filter is not included in the second filter path.

Embodiment 3. The RF circuit of embodiment 1, wherein: the first type of filter response is the low pass filter response, and the second type of filter response is the high pass filter response.

Embodiment 4. The RF circuit of embodiment 3, wherein: the acoustic filter defines an upper passband, a lower passband, and a notch between the upper passband and the lower passband; the lower passband defines an upper band edge, the upper band edge being below a low notch edge of the notch; the upper passband defines a lower band edge, the lower band edge being above a high notch edge of the notch; the acoustic filter has the low pass frequency response with a low pass corner frequency that is at or is below the low notch edge of the notch but above the upper band edge of the lower passband; and the second filter has the high pass frequency response with a high pass corner frequency that is above the high notch edge of the notch but below the lower band edge of the upper passband.

Embodiment 5. The RF circuit of embodiment 4, wherein: the acoustic filter is configured to generate spurious modes above the lower band edge of the upper passband; the low pass frequency response has a first depth between the low notch edge and the high notch edge that is at least as deep as a second depth of the notch; the low pass frequency response is configured to filter the spurious modes above the low band edge of the upper passband; and the high pass corner frequency of the second filter is below the lower band edge of the upper passband but above the high notch edge of the notch.

Embodiment 6. The RF circuit of embodiment 1, wherein: the first type of filter response is the high pass filter response, and the second type of filter response is the low pass filter response.

Embodiment 7. The RF circuit of embodiment 6, wherein: the acoustic filter defines an upper passband, a lower passband, and a notch between the upper passband and the lower passband; the upper passband defines an lower band edge, the lower band edge being above a high notch edge of the notch; the lower passband defines a upper band edge, the upper band edge being below a low notch edge of the notch; the acoustic filter has the high pass frequency response with a high pass corner frequency that is at or is above the high notch edge of the notch but below the lower band edge of the upper passband; and the second filter has the low pass frequency response with a low pass corner frequency that is below the low notch edge of the notch but above the upper band edge of the upper passband.

Embodiment 8. The RF circuit of embodiment 7, wherein: the acoustic filter is configured to generate spurious modes below the upper band edge of the lower passband; the high pass frequency response has a first depth between the low notch edge and the high notch edge that is at least as deep as a second depth of the notch; the high pass frequency response is configured to filter the spurious modes below the high band edge of the lower passband; and the low pass corner frequency of the second filter is above the upper band edge of the lower passband but below the low notch edge of the notch.

Embodiment 9. The RF circuit of embodiment 1, wherein the acoustic filter is a surface acoustic wave (SAW) filter or a bulk acoustic wave (BAW) filter.

Embodiment 10. The RF circuit of embodiment 1, wherein the RF circuit is formed in an integrated circuit (IC) package.

Embodiment 11. A method of filtering a radio frequency (RF) signal, includes: receiving the RF signal at an input terminal; splitting the RF signal so that a first split RF signal is transmitted through a first filter path and a second split RF signal is transmitted through a second filter path; filtering the first split RF signal with an acoustic filter, wherein the acoustic filter defines a notch and a first filter response, wherein the first filter response is a first type of filter response; filtering the second split RF signal with second filter in the second filter path, the second filter being at least one of a lumped element filter and a printed element filter, wherein second filter defines a second type of filter response; recombining the first split RF signal and the second split RF signal into a recombined RF signal; wherein the first type of filter response is one of either a low pass response or a high pass response; and wherein the second type of filter response is of another one of the low pass type filter response or the high pass type filter response.

Embodiment 12. A user element includes a radio frequency (RF) circuit, the RF circuit includes: an input terminal; an output terminal; a first filter path connected between the input terminal and the output terminal, wherein the first filter path includes an acoustic filter that defines a notch and a first filter response, wherein the first filter response is a first type of filter response; a second filter path connected between the input terminal and the output terminal, wherein the second filter path includes a second filter that is at least one of a lumped element filter and a printed element filter, wherein second filter defines a second type of filter response; wherein the first type of filter response is one of either a low pass response or a high pass response; and wherein the second type of filter response is of another one of the low pass response or the high pass response.

Embodiment 13. The user element of embodiment 12, wherein another acoustic filter is not included in the second filter path.

Embodiment 14. The user element of embodiment 12, wherein: the first type of filter response is the low pass filter response, and the second type of filter response is the high pass filter response.

Embodiment 15. The user element of embodiment 14, wherein: the acoustic filter defines an upper passband, a lower passband, and a notch between the upper passband and the lower passband; the lower passband defines an upper band edge, the upper band edge being below a low notch edge of the notch; the upper passband defines a lower band edge, the lower band edge being above a high notch edge of the notch; the acoustic filter has the low pass frequency response with a low pass corner frequency that is at or is below the low notch edge of the notch but above the upper band edge of the lower passband; and the second filter has the high pass frequency response with a high pass corner frequency that is above the high notch edge of the notch but below the lower band edge of the upper passband.

Embodiment 16. The user element of embodiment 15, wherein: the acoustic filter is configured to generate spurious modes above the lower band edge of the upper passband; the low pass frequency response has a first depth between the low notch edge and the high notch edge that is at least as deep as a second depth of the notch; the low pass frequency response is configured to filter the spurious modes above the low band edge of the upper passband; and the high pass corner frequency of the second filter is below the lower band edge of the upper passband but above the high notch edge of the notch.

Embodiment 17. The user element of embodiment 12, wherein: the first type of filter response is the high pass filter response, and the second type of filter response is the low pass filter response.

Embodiment 18. The user element of embodiment 17, wherein: the acoustic filter defines an upper passband, a lower passband, and a notch between the upper passband and the lower passband; the upper passband defines an lower band edge, the lower band edge being above a high notch edge of the notch; the lower passband defines a upper band edge, the upper band edge being below a low notch edge of the notch; the acoustic filter has the high pass frequency response with a high pass corner frequency that is at or is above the high notch edge of the notch but below the lower band edge of the upper passband; and the second filter has the low pass frequency response with a low pass corner frequency that is below the low notch edge of the notch but above the upper band edge of the upper passband.

Embodiment 19. The user element of embodiment 18, wherein: the acoustic filter is configured to generate spurious modes below the upper band edge of the lower passband; the high pass frequency response has a first depth between the low notch edge and the high notch edge that is at least as deep as a second depth of the notch; the high pass frequency response is configured to filter the spurious modes below the high band edge of the lower passband; and the low pass corner frequency of the second filter is above the upper band edge of the lower passband but below the low notch edge of the notch.

Embodiment 20. The user element of embodiment 12, wherein the acoustic filter is a surface acoustic wave (SAW) filter or a bulk acoustic wave (BAW) filter.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 illustrates an RF circuit, in accordance with some embodiments.

FIG. 2 illustrates a frequency response of an acoustic filter of FIG. 1 without taking into account a low pass response of the acoustic filter and with no other components provided, in accordance with some embodiments.

FIG. 3 illustrates a frequency response of the RF circuit shown in FIG. 1, in accordance with some embodiments.

FIG. 4 illustrates an RF circuit, in accordance with some embodiments.

FIG. 5 illustrates a frequency response of the acoustic filter of FIG. 4 without the high pass response of the acoustic filter and when no other components are provided, in accordance with some embodiments.

FIG. 6 illustrates a frequency response of the RF circuit shown in FIG. 4, in accordance with some embodiments.

FIG. 7 illustrates an RF circuit, in accordance with some embodiments.

FIG. 8 illustrates another RF circuit, in accordance with some embodiments.

FIG. 9 illustrates a flow diagram describing a method for filtering an RF signal, in accordance with some embodiments.

FIG. 10 illustrates a user element, in accordance with some embodiments.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that comcomthese concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Radio frequency (RF) circuits are disclosed. The RF circuits include two RF filter paths. One of the RF filter paths includes an acoustic filter, while the other RF filter path (a bypass path) includes a second RF filter. The acoustic filter is configured to provide a notch between a lower passband and an upper passband and, furthermore, a first filter response that is a first type of filter response. The first filter response of the acoustic filter is configured to filter out spurious modes in a section of either one of the passbands. For example, if a section of the upper passband is degraded by spurious modes of the acoustic filter, the first filter response is a low pass frequency response. A low pass corner frequency of the low pass frequency response is provided below the notch and thereby filters out the spurious modes in the upper passband. In contrast, if a section of the lower passband is degraded by spurious modes by the acoustic filter, the first filter response is a high pass filter response. A high pass corner frequency of the high pass filters is provided above the notch and thereby filters out the spurious modes generated by the acoustic filter. The second filter has a second type of filter response that is the opposite of the first filter response and allows portion of the signal in the section with the spurious modes to pass through the other RF path (the bypass path).

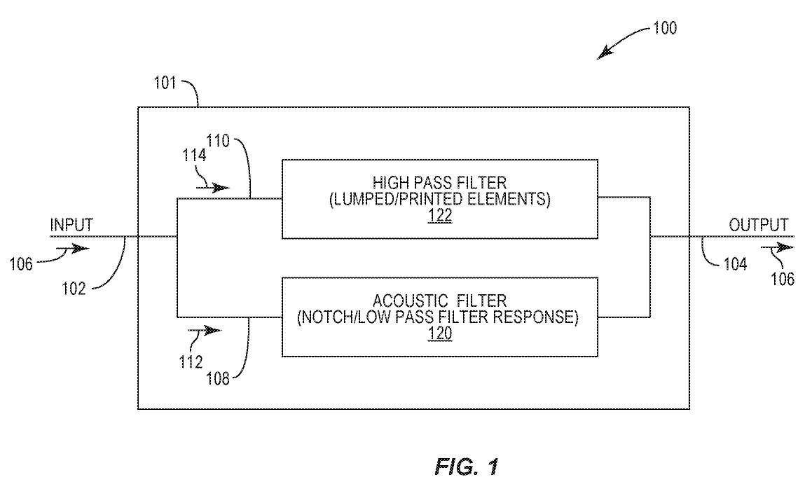

FIG. 1 illustrates an RF circuit 100, in accordance with some embodiments.

The RF circuit 100 shown in FIG. 1 is an RF filter. The RF circuit 100 is provided in a circuit package 101. The RF circuit 100 includes an input terminal 102 and an output terminal 104. An RF signal 106 is received by the RF circuit 100 at the input terminal 102 from external upstream circuitry (not explicitly shown). The RF signal 106 is then filtered by the RF circuit 100 and output at the output terminal 104 into external downstream circuitry (not explicitly shown). In some embodiments, the RF circuit 100 operates to allow for simultaneous reception and transmission of the RF signals 106. Thus, in some embodiments, the input terminal 102 also operates as an output terminal and the output terminal 104 also operates as an input terminal. More specifically, in some embodiments, an RF signal (such as the RF signal 106) is received at the output terminal 104, filtered by the RF circuit 100, and output at the input terminal 102. The RF circuit 100 operates as a notch filter that provides a notch designed to deliver precise rejection capabilities, attenuating a specific frequency or a narrow specific frequency range in the frequency spectrum. The frequencies that fall outside of the frequency range of the notch are unaffected, ensuring minimal signal loss. The sharpness of the notch is important, and the RF circuit 100 is designed to provide a high quality (Q) factor.

The RF circuit 100 includes an RF filter path 108 and an RF filter path 110. The RF filter path 108 is connected between the input terminal 102 and the output terminal 104. Similarly, the RF filter path 110 is connected between the input terminal 102 and the output terminal 104. In other words, there is a split between the input terminal 102 and the output terminal 104 of an RF filter path into the RF filter path 108 and the RF filter path 110. At the input terminal 102, the RF signal 106 is split into an RF signal 112 and an RF signal 114. The RF signal 112 propagates through the RF filter path 108, while the RF signal 114 propagates through the RF filter path 110.

To provide a notch, the RF circuit 100 utilizes an acoustic filter 120. As will explained in further detail below, the acoustic filter 120 is configured to provide an upper passband, a lower passband, and the notch between the upper passband and the lower passband. The acoustic filter 120 is a type of filter that utilizes acoustic waves (typically in piezoelectric materials) to manipulate RF signals 106. The acoustic filter 120 is configured to provide the notch in order to reject specific frequencies within an RF frequency spectrum. The acoustic filter 120 converts an RF signal into mechanical vibrations (i.e., acoustic waves) within a piezoelectric material such as quartz or lithium niobate. These mechanical vibrations propagate through the material and interact with the RF signal, causing frequency-dependent phase shifts or amplitude changes. Various characteristics of the acoustic filter 120 selectively attenuate certain frequencies to provide the notch. The mechanical vibrations are then converted back into the filtered RF signal. The acoustic filter 120 is not without its drawbacks, as it can produce undesirable spurious responses and inherent bulk losses, particularly around the resonant frequencies. These unwanted anomalies can lead to significant amplitude fluctuations and increased insertion losses within the passbands. In some embodiments, the acoustic filter 120 is a bulk acoustic wave (BAW) filter and/or a surface acoustic wave (SAW) filter. In some embodiments, the acoustic filter 120 is temperature compensated.

In addition to the notch, the acoustic filter 120 is configured to have a low pass response. Accordingly, the RF signal 112 is filtered by notch and the low pass response of the acoustic filter 120. It should be noted that in some embodiments, the acoustic filter 120 is configured to define the notch and the low pass response both looking into the input terminal 102 and looking into the output terminal 104.

With respect to the RF filter path 110, the RF filter path 110 includes a high pass filter 122. The high pass filter 122 has a high pass response. Accordingly, the RF signal 114 is filtered by the high pass response of the high pass filter 122. After filtering, the RF signal 112 and the RF signal 114 are recombined at the output terminal 104 as the RF signal 106. The filtered RF signal 106 is then transmitted externally. The high pass filter 122 is formed from one or more lumped element and/or one or more printed elements. It should be noted that in some embodiments, the high pass filter 122 is configured to define the high pass response both looking into the input terminal 102 and looking into the output terminal 104. Lumped elements in a circuit are discrete electrical components such as resistors, capacitors, and inductors, which are modeled under the assumption that their physical size is negligible compared with the wavelength of the signals with which they interact. A printed element refers to electrical components, such as resistors, capacitors, or inductors, that are formed directly on a laminate of the circuit package 101 through processes such as printing conductive materials or embedding them within the laminate’s layer structure. It should be noted that some lumped elements and/or printed elements may be used with the acoustic filter 120 in order to tune the notch and the low pass response.

The acoustic filter 120 is provided in the RF circuit 100 but generates spurious modes, as will be explained in further detail below. The RF circuit 100 provides the acoustic filter 120 in the RF filter path 108, where the spurious responses caused by the acoustic filter 120 are filtered out by the low pass filter response of the acoustic filter 120. In some embodiments, the low pass response is provided at the input terminal 102 and at the output terminal 104. The RF filter path 110 serves as a bypass path that allows portions of the RF signal 106 that are in the frequency ranges of the spurious responses to pass to the output terminal 104. The high pass response of the high pass filter 122 defines a corner frequency that allows the portions of the RF signal 106 that are in the frequency ranges of the spurious responses to pass to the output terminal 104. In some embodiments, the high pass response of high pass filter 122 is provided at the input terminal 102 and is provided at the output terminal 104. Filter topologies of the high pass filter 122 may be Butterworth, Chebyshev, inverse Chebyshev, Cauer (elliptic), or the like.

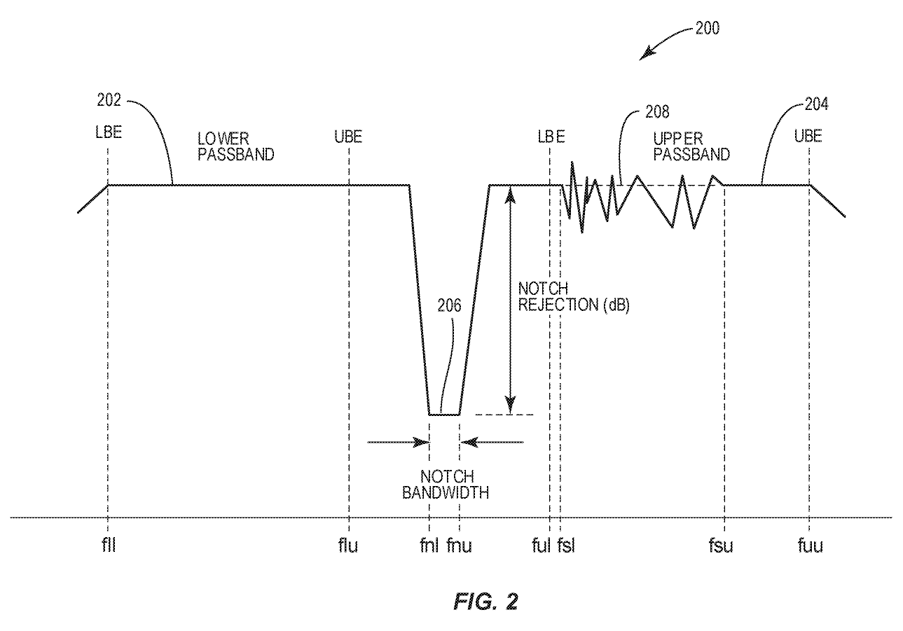

FIG. 2 illustrates a frequency response 200 of the acoustic filter 120 of FIG. 1 without taking into account the low pass response and with no other components provided, in accordance with some embodiments.

The acoustic filter 120 is configured to provide a lower passband 202, an upper passband 204, and a notch 206 between the upper passband 204 and the lower passband 202. The lower passband 202 is configured to pass frequencies between a lower band edge (LBE) at a frequency fll and an upper band edge (UBE) at a frequency flu. The notch 206 is configured to reject frequencies between a lower notch edge at a frequency fnl and an upper notch edge at a frequency fnu. The upper passband 204 is configured to pass frequencies between a lower band edge at a frequency ful and an upper band edge at frequency fuu. However, the acoustic filter 120 is configured to generate spurious modes above the lower band edge frequency ful that degrade a section 208 of the upper passband 204. The section 208 between the lower band edge frequency ful and the upper band edge frequency fuu of the upper passband 204 is distorted. In this example, the section 208 of the upper passband 204 that is distorted by spurious modes is provided between a lower band edge frequency fsl and an upper band edge frequency fsu. The RF circuit 100 shown in FIG. 1 is configured to remove the spurious modes caused by the acoustic filter 120 and thereby to pass portions of the RF signal 106 that are in the section 208 with reduced distortion.

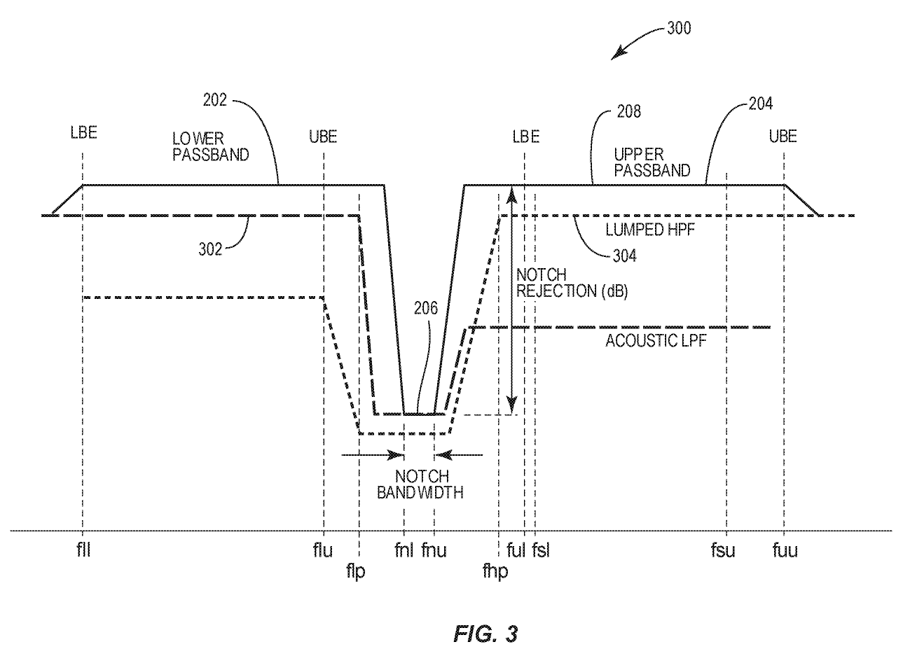

FIG. 3 illustrates a frequency response 300 of the RF circuit 100 shown in FIG. 1, in accordance with some embodiments.

The frequency response 300 has the lower passband 202, the upper passband 204 and the notch 206 as described above with respect to FIG. 2. However, as shown here in FIG. 3, the section 208 as shown in FIG. 2 is not distorted by the spurious modes of the acoustic filter 120.

Referring now to FIGS. 1 and 3, the acoustic filter 120 is configured to provide a low pass response 302 (also referred to as the low pass frequency response 302). It should be noted that, in different embodiments, the low pass frequency response 302 of each of the low pass responses 302 of the acoustic filter 120 may not be exactly the same at the input terminal 102 and the output terminal 104 and may be somewhat misaligned with respect to each of the input terminal 102 and the output terminal 104. In this embodiment, the low pass frequency response 302 of acoustic filter 120 has a low pass corner frequency flp that is below the lower notch edge at the frequency fnl of the notch 206 but above the upper band edge at the frequency flu of the lower passband 202. More specifically, the low pass corner frequency flp is thus below the lower band edge at the frequency fsl of the section 208. The low pass frequency response 302 has a depth that is at least as great as the depth of the notch 206 throughout the frequency range (frequency range between frequencies fnl and fnu) of the notch 306. Above the upper band edge at frequency fnu of the notch 206, the low pass frequency response 302 may degrade and thus not have a depth as deep as the notch 206. Nevertheless, even with the degradation, the depth of the low pass frequency response 302 is sufficient to filter the spurious modes caused by the acoustic filter 120 in the filer path 108. In this manner, the low pass frequency response 302 of the acoustic filter 120 filters out the spurious modes generated in the section 208. Also, the section 208 of the upper passband 204 is not degraded. Thus, the portion of the RF signal 106 that is below the low pass corner frequency flp is passed as the split RF signal 112 in the filter path 108 and is filtered by the notch 206 of the acoustic filter 120. The notch 206 of the acoustic filter 120 filters the split RF signal 112. In this case, the rejection of the low pass frequency response 302 in the upper passband 204 has to be sufficient to properly attenuate unwanted spurious and bulk losses. Depending on the severity, 10dB to 20dB of rejection for each of the low pass frequency response 302 in the frequency range of the section 208 is adequate.

In this embodiment, the high pass filter 122 in the RF filter path 110 has a high pass frequency response 304 both at the input terminal 102 and at the output terminal 104. It should be noted that, in different embodiments, the high pass frequency response 304 may not be exactly the same at the input terminal 102 and the output terminal 104 and may be somewhat misaligned with respect to the input terminal 102 and the output terminal 104. In this embodiment, the high pass frequency response 304 of the high pass filter 122 has a high pass corner frequency fhp that is at or above the upper notch edge at the frequency fnu of the notch 206 but below the lower band edge of the upper passband 204 at frequency ful. More specifically, the high pass corner frequency fhp is also below the lower band edge frequency fsl of the section 208. In this manner, the high pass frequency response 304 of the high pass filter 122 passes portions of the RF signal 106 that are aligned with the section 208 of the upper passband 204. More specifically, the portion of the RF signal 106 that is above the high pass corner frequency fhp is passed as the split RF signal 114. In this manner, the low pass frequency response 302 rejects the spurious modes and bulk losses that would degrade the section 208, but the portion of the RF signal 106 that is aligned by the section 208 in the upper passband 204 is passed through the RF filter path 110. For the high pass filter 122, the high pass corner frequency fhp is also above the upper notch edge at the frequency fnu, and the rejection of the high pass filter 122 in the frequency range (between frequency fnl and frequency fnu) is at least as deep as the rejection from the depth of the notch 206. The exact amount of rejection of the high pass filter 122 depends on many factors, including production margins, component tolerances, acoustic variations, and temperature. Below the low notch edge at frequency fnl, the high pass frequency response 304 may degraded to be above the depth of the notch 206. Nevertheless, the high pass frequency response 304 provides sufficient rejection in the frequency range of the lower passband 202.

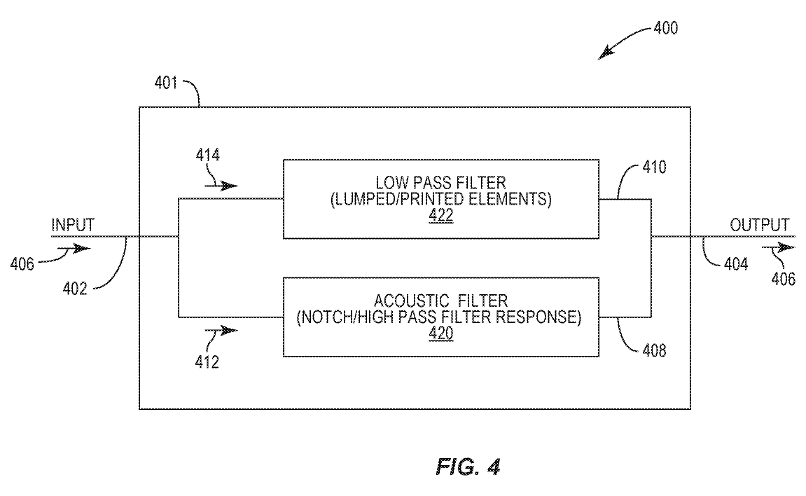

FIG. 4 illustrates an RF circuit 400, in accordance with some embodiments.

The RF circuit 400 shown in FIG. 4 is an RF filter. The RF circuit 400 is provided in a circuit package 401. The RF circuit 400 includes an input terminal 402 and an output terminal 404. An RF signal 406 is received by the RF circuit 400 at the input terminal 402 from external upstream circuitry (not explicitly shown). The RF signal 406 is then filtered by the RF circuit 400 and output at the output terminal 404 into external downstream circuitry (not explicitly shown). In some embodiments, the RF circuit 400 operates to allow for simultaneous reception and transmission of the RF signals 406. Thus, in some embodiments, the input terminal 402 also operates as an output terminal and the output terminal 404 also operates as an input terminal. More specifically, in some embodiments, an RF signal (such as the RF signal 406) is received at the output terminal 404, filtered by the RF circuit 400, and output at the input terminal 402.

The RF circuit 400 operates as a notch filter that provides a notch designed to deliver precise rejection capabilities, attenuating a specific frequency or a narrow specific frequency range in the frequency spectrum. The frequencies that fall outside of the frequency range of the notch are unaffected, ensuring minimal signal loss. The sharpness of the notch is important and the RF circuit 400 is designed to provide a low Q factor.

The RF circuit 400 includes an RF filter path 408 and an RF filter path 410. The RF filter path 408 is connected between the input terminal 402 and the output terminal 404. Similarly, the RF filter path 410 is connected between the input terminal 402 and the output terminal 404. In other words, there is a split between the input terminal 402 and the output terminal 404 of an RF filter path into the RF filter path 408 and the RF filter path 410. At the input terminal 402, the RF signal 406 is split into an RF signal 412 and an RF signal 414. The RF signal 412 propagates through the RF filter path 408, while the RF signal 414 propagates through the RF filter path 410.

To provide a notch, the RF circuit 400 utilizes an acoustic filter 420. As will explained in further detail below, the acoustic filter 420 is configured to provide a lower passband, an upper passband, and the notch between the lower passband and the upper passband. The acoustic filter 420 is a type of filter that utilizes acoustic waves (typically in piezoelectric materials) to manipulate RF signals 406. The acoustic filter 420 is configured to provide the notch in order to reject specific frequencies within an RF frequency spectrum. The acoustic filter 420 converts an RF signal into mechanical vibrations (i.e., acoustic waves) within a piezoelectric material such as quartz or lithium niobate. These mechanical vibrations propagate through the material and interact with the RF signal, causing frequency-dependent phase shifts or amplitude changes. Various characteristics of the acoustic filter 420 selectively attenuate certain frequencies to provide the notch. The mechanical vibrations are then converted back into the filtered RF signal. The acoustic filter 420 is not without its drawbacks, as they can produce undesirable spurious responses and inherent bulk losses, particularly around the resonant frequencies. These unwanted anomalies can lead to significant amplitude fluctuations and increased insertion losses within the passbands. In some embodiments, the acoustic filter 420 is a BAW filter and/or a SAW filter. In some embodiments, the acoustic filter 420 is temperature compensated.

In addition to the notch, the acoustic filter 420 is configured to have a high pass response. Accordingly, the RF signal 412 is filtered by notch and the high pass response of the acoustic filter 420. It should be noted that, in some embodiments, the acoustic filter 420 is configured to define the notch and the high pass response both looking into the input terminal 402 and looking into the output terminal 404.

With respect to the RF filter path 410, the RF filter path 410 includes a low pass filter 422. The low pass filter 422 has a low pass response. Accordingly, the RF signal 414 is filtered by the low pass response of the low pass filter 422. After filtering, the RF signal 412 and the RF signal 414 are recombined at the output terminal 404 as the RF signal 406. The filtered RF signal 406 is then transmitted externally. The low pass filter 422 is formed from one or more lumped elements and/or one or more printed elements. It should be noted that in some embodiments the low pass filter 422 is configured to define the low pass response both looking into the input terminal 402 and looking into the output terminal 404. It should be noted that some lumped elements and/or printed elements may be used with the acoustic filter 420 in order to tune the notch and the low pass response.

The acoustic filter 420 is provided in the RF circuit 400 but generates spurious modes, as will be explained in further detail below. The RF circuit 400 provides the acoustic filter 420 in the RF filter path 408, where the spurious responses caused by the acoustic filter 420 are filtered out by the high pass filter response of the acoustic filter 420. In some embodiments, the high pass response is provided at the input terminal 402 and at the output terminal 404. The RF filter path 410 serves as a bypass path that allows portions of the RF signal 406 that are in the frequency ranges of the spurious responses to pass to the output terminal 404. The low pass response of the low pass filter 422 defines a corner frequency that allows the portions of the RF signal 406 that are in the frequency ranges of the spurious responses to pass to the output terminal 404. In some embodiments, the low pass response of low pass filter 422 is provided at the input terminal 402 and is provided at the output terminal 404. Filter topologies of the low pass filter 422 may be Butterworth, Chebyshev, inverse Chebyshev, Cauer (elliptic), or the like.

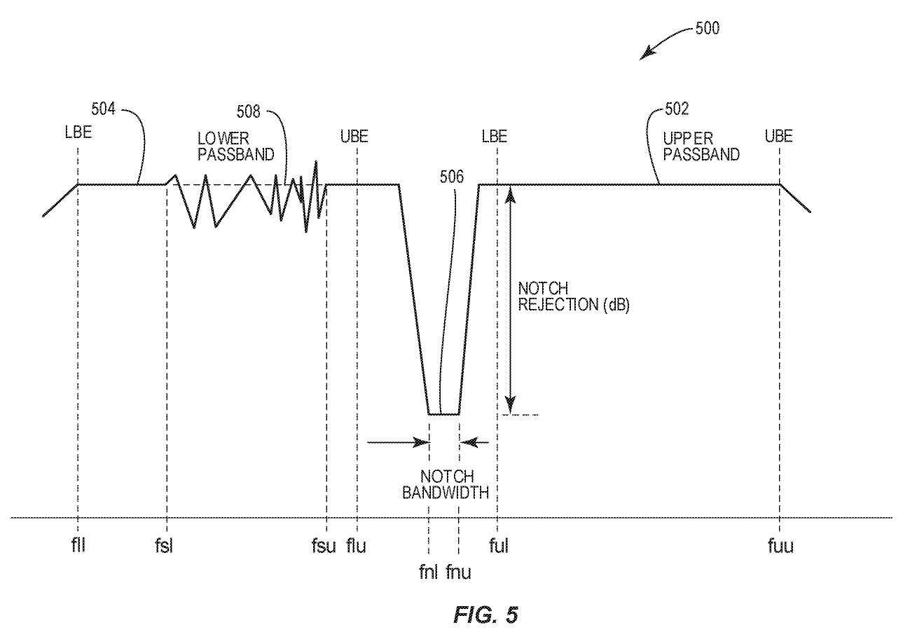

FIG. 5 illustrates a frequency response 500 of the acoustic filter 420 of FIG. 4 without the high pass response and when no other components are provided, in accordance with some embodiments.

The acoustic filter 420 is configured to provide an upper passband 502, a lower passband 504, and a notch 506 between the lower passband 504 and the upper passband 502. The upper passband 502 is configured to pass frequencies between an upper band edge (UBE) at a frequency fuu and a lower band edge (LBE) at a frequency ful. The notch 506 is configured to reject frequencies between an upper notch edge at a frequency fnu and a lower notch edge at a frequency fnl. The lower passband 504 is configured to pass frequencies between an upper band edge at a frequency flu and a lower band edge at a frequency fll. However, the acoustic filter 420 is configured to generate spurious modes above the lower band edge at the frequency fll but below the upper band edge at the frequency flu that degrade a section 508 of the lower passband 504. The section 508 is between the upper band edge at the frequency flu and the lower band edge at the frequency fll of the lower passband 504. The section 508 is distorted. In this example, the section 508 of the lower passband 504 that is distorted by the spurious modes is provided between a higher frequency of fsu and a lower frequency of fsl. The RF circuit 400 as shown in FIG. 4 is configured to remove the spurious modes caused by the acoustic filter 420 and thereby to pass portions of the RF signal 406 that are in the section 508 with or without reduced distortion.

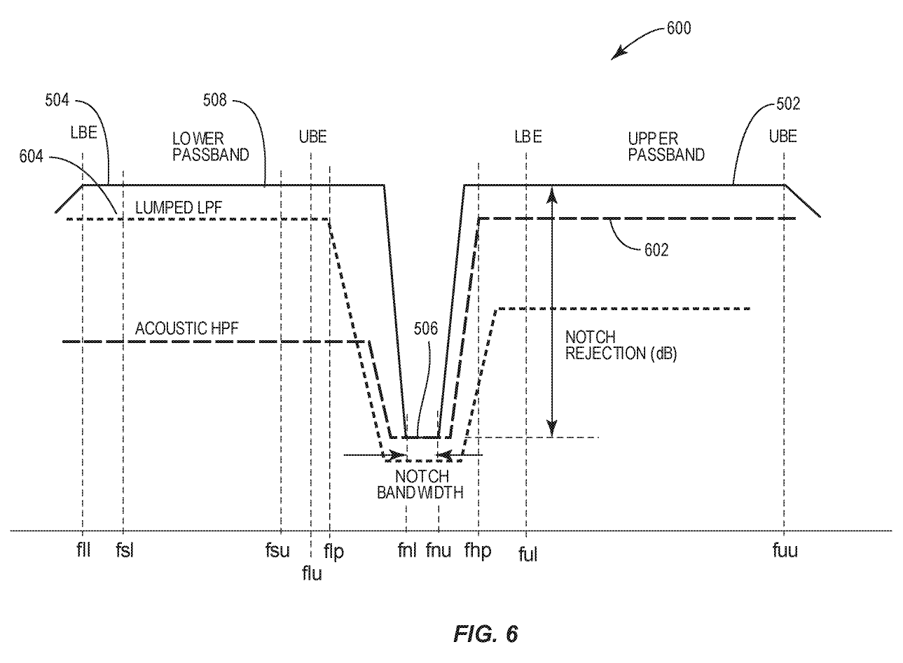

FIG. 6 illustrates a frequency response 600 of the RF circuit 400 shown in FIG. 4, in accordance with some embodiments.

The frequency response 600 has the upper passband 502, the lower passband 504, and the notch 506 as described above with respect to FIG. 5. However, as shown here in FIG. 6, the section 508 as shown in FIG. 5 is not distorted by the spurious modes of the acoustic filter 120.

Referring now to FIGS. 1 and 6, the acoustic filter 120 is configured to provide a high pass response 602 (also referred to as the high pass frequency response 602). It should be noted that in different embodiments the high pass frequency response 602 of each of the high pass responses 602 of the acoustic filter 120 may not be exactly the same at the input terminal 102 and the output terminal 104 and may be somewhat misaligned with respect to each of the input terminal 102 and the output terminal 104. In this embodiment, the high pass frequency response 602 of acoustic filter 120 has a high pass corner frequency fhp that is above the upper notch edge at the frequency fnu of the notch 506 but below the lower band edge at the frequency ful of the upper passband 502. More specifically, the high pass corner frequency fhp is thus above the upper band edge at the frequency fsu of the section 508. The high pass frequency response 602 has a depth that is at least as great as the depth of the notch 506 throughout the frequency range (frequency range between frequencies fnl and fnu) of the notch 506. Above the lower band edge at frequency fnu of the notch 506, the high pass frequency response 602 may degrade and thus not have a depth as deep as the notch 506. Nevertheless, even with the degradation, the depth of the high pass frequency response 602 is sufficient to filter the spurious modes caused by the acoustic filter 120 in the filer path 108. In this manner, the high pass frequency response 602 of the acoustic filter 120 filters out the spurious modes it generates in the section 508. Also, the section 508 of the lower passband 504 is not degraded. Thus, the portion of the RF signal 106 that is above the high pass corner frequency fhp is passed as the split RF signal 112 in the filter path 108 and is filtered by the notch 506 of the acoustic filter 120. The notch 506 of the acoustic filter 120 filters the split RF signal 112. In this case, the rejection of the high pass frequency response 602 in the lower passband 504 has to be sufficient to properly attenuate unwanted spurious and bulk losses. Depending on the severity, 10dB to 50dB of rejection for each of the high pass frequency response 602 in the frequency range of the section 508 is adequate.

In this embodiment, the low pass filter 422 in the RF filter path 110 has a low pass frequency response 604 both at the input terminal 102 and at the output terminal 104. It should be noted that in different embodiments the low pass frequency response 604 may not be exactly the same at the input terminal 102 and the output terminal 104 and may be somewhat misaligned with respect to the input terminal 102 and the output terminal 104. In this embodiment, the low pass frequency response 604 of the low pass filter 422 has a low pass corner frequency flp that is at or below the lower notch edge at the frequency fnl of the notch 506 but above the upper band edge of the lower passband 504 at frequency flu. More specifically, the low pass corner frequency flp is also above the frequency fsu of the section 508. In this manner, the low pass frequency response 604 of the low pass filter 422 passes portions of the RF signal 106 that are aligned with the section 508 of the lower passband 504. More specifically, the portion of the RF signal 106 that is below the low pass corner frequency flp is passed as the split RF signal 114. In this manner, the high pass frequency response 602 rejects the spurious modes and bulk losses that would degrade the section 508, but the portion of the RF signal 106 that is aligned by the section 508 in the lower passband 504 is passed through the RF filter path 110. For the low pass filter 422, the low pass corner frequency flp is also below the lower notch edge at the frequency fnl, and the rejection of the low pass filter 422 in the frequency range (between frequency fnl and frequency fnu) is at least as deep as the rejection from the depth of the notch 506. The exact amount of rejection of the low pass filter 422 depends on many factors, including production margins, component tolerances, acoustic variations, and temperature. Above the upper notch edge at frequency fnu, the low pass frequency response 604 may degraded to be above the depth of the notch 506. Nevertheless, the low pass frequency response 604 provides sufficient rejection in the frequency range of the upper passband 502.

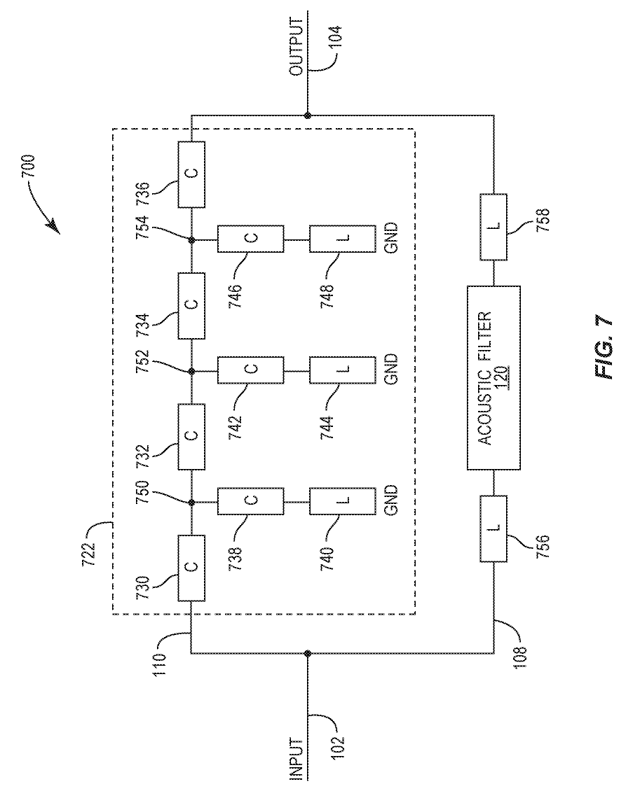

FIG. 7 illustrates an RF circuit 700, in accordance with some embodiments.

The RF circuit 700 is an embodiment of the RF circuit 100 shown in FIGS. 1 and 3. The RF circuit 700 includes the input terminal 102, the output terminal 104, the RF filter path 108, the RF filter path 110, and the acoustic filter 120, which operate in the same manner as described above. The RF circuit 700 includes a high pass filter 722 in the RF filter path 110. The high pass filter 722 is an example of the high pass filter 122 described in FIG. 1 and operates in the manner described above with respect to FIGS. 1 and 3.

The high pass filter 722 is a ladder network of lumped elements and provides a high pass response as described above in FIGS. 1 and 3. The high pass filter 722 includes a capacitive device 730, a capacitive device 732, a capacitive device 734, a capacitive device 736, a capacitive device 738, an inductive device 740, a capacitive device 742, an inductive device 744, a capacitive device 746, and an inductive device 748.

A first side of the capacitive device 730 is coupled to the input terminal 102, while a second end of the capacitive device 730 is coupled to a node 750. The capacitive device 738 and the inductive device 740 are connected in series within a shunt path that is connected between the node 750 and ground (GND). A first side of the capacitive device 732 is coupled to the node 750, while a second end of the capacitive device 732 is coupled to a node 752. The capacitive device 742 and the inductive device 744 are connected in series within a shunt path that is connected between the node 752 and ground. A first side of the capacitive device 734 is coupled to the node 752 while a second end of the capacitive device 734 is coupled to a node 754. The capacitive device 746 and the inductive device 748 are connected in series within a shunt path that is connected between the node 754 and ground. A first side of the capacitive device 736 is coupled to the node 754 while a second end of the capacitive device 736 is coupled to the output terminal 104.

Thus, in this embodiment, the high pass filter 722 is said to have three ladder rungs because three shunt paths between a pair of the capacitive devices 730, 732, 734, 736. It should be noted that in other embodiments, the ladder network of lumped elements may have any number of ladder rungs.

In FIG. 7, the RF circuit 700 includes an inductive device (lumped inductor) 756 and an inductive device (lumped inductor) 758 in the RF filter path 108. More specifically, the inductive device 756 is connected between the input terminal 102 and the acoustic filter 120, while the inductive device 758 is connected between the acoustic filter 120 and the output terminal 104. The inductive device 756 provides matching at the input terminal 102 so that the capacitive device 730 does not load the input terminal 102. The inductive device 758 provides matching at the output terminal 104 so that the capacitive device 736 does not load the output terminal 104.

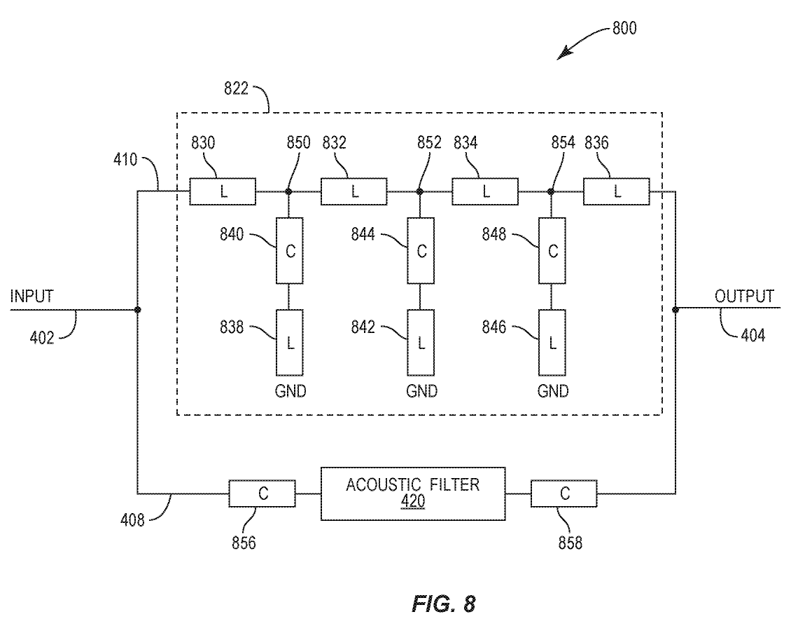

FIG. 8 illustrates an RF circuit 800, in accordance with some embodiments.

The RF circuit 800 is an embodiment of the RF circuit 400 shown in FIGS. 4 and 5. The RF circuit 800 includes the input terminal 402, the output terminal 404, the RF filter path 408, the RF filter path 410, and the acoustic filter 420, which operate in the same manner as described above. The RF circuit 800 includes a low pass filter 822 in the RF filter path 410. The low pass filter 822 is an example of the low pass filter 422 described in FIG. 4 and operates in the manner described above with respect to FIGS. 4 and 5.

The low pass filter 822 is a ladder network of lumped elements and provides a low pass response as described above in FIGS. 4 and 5. The low pass filter 822 includes an inductive device 830, an inductive device 832, an inductive device 834, an inductive device 836, an inductive device 838, a capacitive device 840, an inductive device 842, a capacitive device 844, an inductive device 846, and a capacitive device 848.

A first side of the inductive device 830 is coupled to the input terminal 402, while a second end of the inductive device 830 is coupled to a node 850. The inductive device 838 and the capacitive device 840 are connected in series within a shunt path that is connected between the node 850 and ground (GND). A first side of the inductive device 832 is coupled to the node 850, while a second end of the inductive device 832 is coupled to a node 852. The inductive device 842 and the capacitive device 844 are connected in series within a shunt path that is connected between the node 852 and ground. A first side of the inductive device 834 is coupled to the node 852, while a second end of the inductive device 834 is coupled to a node 854. The inductive device 846 and the capacitive device 848 are connected in series within a shunt path that is connected between the node 854 and ground. A first side of the inductive device 836 is coupled to the node 854, while a second end of the inductive device 836 is coupled to the output terminal 404.

Thus, in this embodiment, the low pass filter 822 is said to have three ladder rungs because three shunt paths between a pair of the inductive devices 830, 832, 834, 836. It should be noted that in other embodiments, the ladder network of lumped elements may have any number of ladder rungs.

In FIG. 8, the RF circuit 800 includes a capacitive device (lumped capacitor) 856 and a capacitive device (lumped capacitor) 858 in the RF filter path 408. More specifically, the capacitive device 856 is connected between the input terminal 402 and the acoustic filter 420, while the capacitive device 858 is connected between the acoustic filter 420 and the output terminal 404. The capacitive device 856 provides matching at the input terminal 402 so that the inductive device 830 does not load the input terminal 402. The capacitive device 858 provides matching at the output terminal 404 so that the inductive device 836 does not load the output terminal 404.

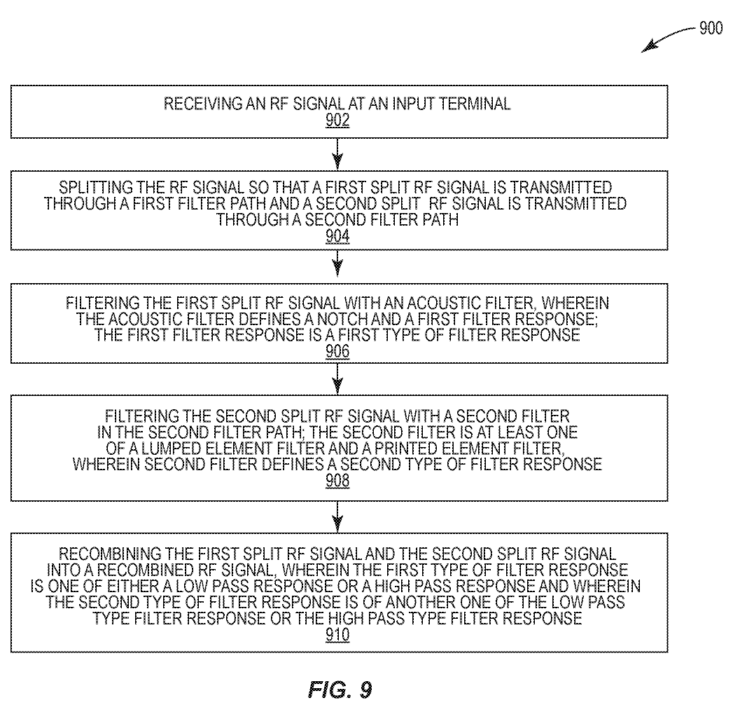

FIG. 9 illustrates a flow diagram 900 describing a method for filtering an RF signal, in accordance with some embodiments.

In some embodiments, the method of FIG. 9 is performed by the RF circuit 100 in FIG. 1, the RF circuit 400 in FIG. 4, the RF circuit 700 in FIG. 7, or the RF circuit 800 in FIG. 8. In some embodiments, the RF signal of FIG. 9 is the RF signal 106 in FIG. 1 or the RF signal 406 in FIG. 4. The flow diagram 900 includes blocks 902 to 918. Flow begins at block 902.

At block 902, an RF signal is received at an input terminal. In some embodiments, the RF signal is the RF signal 106 in FIG. 1 or the RF signal 406 in FIG. 4. In some embodiments, the input terminal is the input terminal 102 in FIGS. 1 and 7 or the input terminal 402 in FIGS. 4 and 8. Flow then proceeds to block 904.

At block 904, the RF signal is split so that a first split RF signal is transmitted through a first filter path and a second split RF signal is transmitted through a second filter path. In some embodiments, the first split RF signal is the split RF signal 112 in FIG. 1 or the split RF signal 412 in FIG. 4. In some embodiments, the second split RF signal is the split RF signal 114 in FIG. 1 or the split RF signal 414 in FIG. 4. In some embodiments, the first filter path is the filter path 108 in FIGS. 1 and 7 or the filter path 408 in FIGS. 4 and 8. In some embodiments, the second filter path is the RF filter path 110 in FIGS. 1 and 7 or the filter path 410 in FIGS. 4 and 8. Flow then proceeds to block 906.

At block 906, the first split RF signal is filtered with the acoustic filter, wherein the acoustic filter defines a notch and a first filter response, and the first filter response is a first type of filter response. In some embodiments, the first filter response is the low pass frequency response 302 shown in FIG. 3 or the high pass frequency response 602 shown in FIG. 6 . In some embodiments, the notch is the notch 206 shown in FIG. 3 or the notch 506 shown in FIG. 6. In some embodiments, the acoustic filter is the acoustic filter 120 in FIG. 1 or the acoustic filter 420 in FIG. 4. Flow then proceeds to block 908.

At block 908, the second split RF signal is filtered with a second filter in the second filter path. In some embodiments, the second filter is the high pass filter 122 shown in FIG. 1, the high pass filter 722 shown in FIG. 7, the low pass filter 422 shown in FIG. 4 or the low pass filter 822 shown in FIG. 8. Flow the proceeds to block 910.

At block 910, the first split RF signal and the second split RF signal are recombined into a recombined RF signal, wherein the first type of filter response is one of either a low pass response or a high pass response and wherein the second type of filter response is of another one of the low pass type filter response or the high pass type filter response. In FIG. 1, the split RF signal 112 and the split RF signal 114 are recombined into the RF signal 106 at the output terminal 104. For FIG. 1, the first type of filter response is the low pass frequency response 302 in FIG. 3 and the second type of filter response is the high pass frequency response 304 in FIG. 3. In FIG. 4, the split RF signal 412 and the split RF signal 414 are recombined into the RF signal 406 at the output terminal 404. For FIG. 4, the first type of filter response is the high pass frequency response 602 in FIG. 6 and the second type of filter response is the low pass frequency response 604 in FIG. 6.

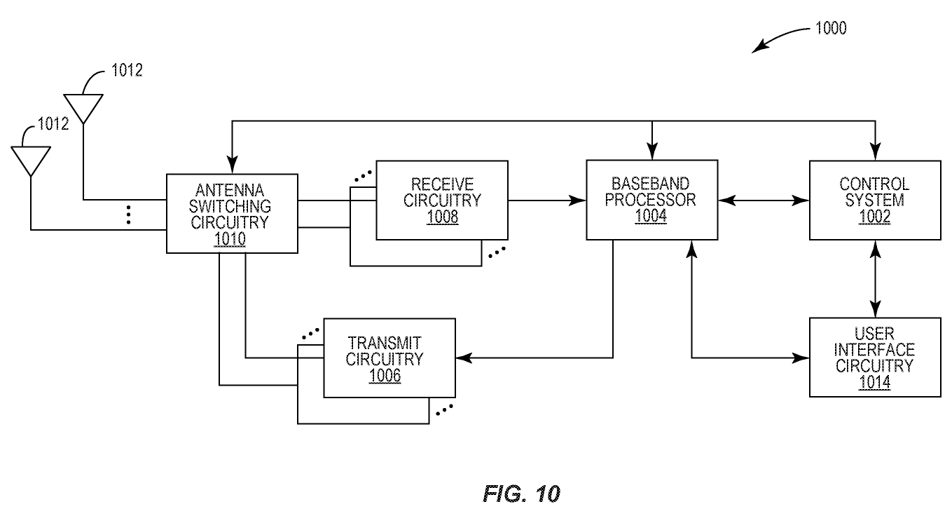

FIG. 10 illustrates a user element 1000, in accordance with some embodiments.

With reference to FIG. 10, the concepts described above may be implemented in various types of user elements 1000, such as mobile terminals, smart watches, tablets, computers, navigation devices, access points, and like wireless communication devices that support wireless communications, such as cellular, wireless local area network (WLAN), Bluetooth, and near-field communications. The user element 1000 will generally include a control system 1002, a baseband processor 1004, transmit circuitry 1006, receive circuitry 1008, antenna switching circuitry 1010, multiple antennas 1012, and user interface circuitry 1014. In a non-limiting example, the control system 1002 may be a field-programmable gate array (FPGA) or an application-specific integrated circuit (ASIC). In this regard, the control system 1002 may include at least a microprocessor, an embedded memory circuit, and a communication bus interface. The receive circuitry 1008 receives radio frequency signals via the antennas 1012 and through the antenna switching circuitry 1010 from one or more base stations. A low-noise amplifier and a filter cooperate to amplify and remove broadband interference from the received signal for processing. Down conversion and digitization circuitry (not shown) will then down convert the filtered, received signal to an intermediate or baseband frequency signal, which is then digitized into one or more digital streams using analog-to-digital converters (ADCs).

The baseband processor 1004 processes the digitized received signal to extract the information or data bits conveyed in the received signal. This processing typically comprises demodulation, decoding, and error correction operations, as will be discussed in greater detail below. The baseband processor 1004 is generally implemented in one or more digital signal processors (DSPs) and ASICs.

For transmission, the baseband processor 1004 receives digitized data, which may represent voice, data, or control information, from the control system 1002, which it encodes for transmission. The encoded data is output to the transmit circuitry 1006, where a digital-to-analog converter (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 1012 through the antenna switching circuitry 1010. The multiple antennas 1012 and the replicated transmit circuitry 1006 and receive circuitry 1008 may provide spatial diversity. Modulation and processing details will be understood by those skilled in the art.

Those skilled in the art will recognize improvements and modifications to the preferred embodiments of the present disclosure. All such improvements and modifications are considered within the scope of the concepts disclosed herein and the claims that follow.

What is claimed is:

1. A radio frequency (RF) circuit, comprising:
an input terminal;
an output terminal;
a first filter path connected between the input terminal and the output terminal, wherein the first filter path includes an acoustic filter that defines a notch and a first filter response, wherein the first filter response is a first type of filter response;
a second filter path connected between the input terminal and the output terminal, wherein the second filter path includes a second filter that is at least one of a lumped element filter and a printed element filter, wherein second filter defines a second type of filter response;
wherein the first type of filter response is one of either a low pass response or a high pass response; and
wherein the second type of filter response is of another one of the low pass type filter response or the high pass type filter response.

2. The RF circuit of claim 1, wherein another acoustic filter is not included in the second filter path.

3. The RF circuit of claim 1, wherein:
the first type of filter response is the low pass filter response and the second type of filter response is the high pass filter response.

4. The RF circuit of claim 3, wherein:
the acoustic filter defines an upper passband, a lower passband, and a notch between the upper passband and the lower passband;
the lower passband defines an upper band edge, the upper band edge being below a low notch edge of the notch;
the upper passband defines a lower band edge, the lower band edge being above a high notch edge of the notch;
the acoustic filter has the low pass frequency response with a low pass corner frequency that is at or is below the low notch edge of the notch but above the upper band edge of the lower passband; and
the second filter has the high pass frequency response with a high pass corner frequency that is above the high notch edge of the notch but below the lower band edge of the upper passband.

5. The RF circuit of claim 4, wherein:
the acoustic filter is configured to generate spurious modes above the lower band edge of the upper passband;
the low pass frequency response has a first depth between the low notch edge and the high notch edge that is at least as deep as a second depth of the notch;
the low pass frequency response is configured to filter the spurious modes above the low band edge of the upper passband; and
the high pass corner frequency of the second filter is below the lower band edge of the upper passband but above the high notch edge of the notch.

6. The RF circuit of claim 1, wherein:
the first type of filter response is the high pass filter response and the second type of filter response is the low pass filter response.

7. The RF circuit of claim 6, wherein:
the acoustic filter defines an upper passband, a lower passband, and a notch between the upper passband and the lower passband;
the upper passband defines an lower band edge, the lower band edge being above a high notch edge of the notch;
the lower passband defines a upper band edge, the upper band edge being below a low notch edge of the notch;
the acoustic filter has the high pass frequency response with a high pass corner frequency that is at or is above the high notch edge of the notch but below the lower band edge of the upper passband; and
the second filter has the low pass frequency response with a low pass corner frequency that is below the low notch edge of the notch but above the upper band edge of the upper passband.

8. The RF circuit of claim 7, wherein:
the acoustic filter is configured to generate spurious modes below the upper band edge of the lower passband;
the high pass frequency response has a first depth between the low notch edge and the high notch edge that is at least as deep as a second depth of the notch;
the high pass frequency response is configured to filter the spurious modes below the high band edge of the lower passband; and
the low pass corner frequency of the second filter is above the upper band edge of the lower passband but below the low notch edge of the notch.

9. The RF circuit of claim 1, wherein the acoustic filter is a surface acoustic wave (SAW) filter or a bulk acoustic wave (BAW) filter.

10. The RF circuit of claim 1, wherein the RF circuit is formed in an integrated circuit (IC) package.

11. A method of filtering a radio frequency (RF) signal, comprising:
receiving the RF signal at an input terminal;
splitting the RF signal so that a first split RF signal is transmitted through a first filter path and a second split RF signal is transmitted through a second filter path;
filtering the first split RF signal with an acoustic filter, wherein the acoustic filter defines a notch and a first filter response, wherein the first filter response is a first type of filter response;
filtering the second split RF signal with second filter in the second filter path, the second filter being at least one of a lumped element filter and a printed element filter, wherein second filter defines a second type of filter response;
recombining the first split RF signal and the second split RF signal into a recombined RF signal;
wherein the first type of filter response is one of either a low pass response or a high pass response; and
wherein the second type of filter response is of another one of the low pass type filter response or the high pass type filter response.

12. A user element comprising a radio frequency (RF) circuit, the RF circuit comprising:
an input terminal;
an output terminal;
a first filter path connected between the input terminal and the output terminal, wherein the first filter path includes an acoustic filter that defines a notch and a first filter response, wherein the first filter response is a first type of filter response;
a second filter path connected between the input terminal and the output terminal, wherein the second filter path includes a second filter that is at least one of a lumped element filter and a printed element filter, wherein second filter defines a second type of filter response;
wherein the first type of filter response is one of either a low pass response or a high pass response; and
wherein the second type of filter response is of another one of the low pass response or the high pass response.

13. The user element of claim 12, wherein another acoustic filter is not included in the second filter path.

14. The user element of claim 12, wherein:
the first type of filter response is the low pass filter response and the second type of filter response is the high pass filter response.

15. The user element of claim 14, wherein:
the acoustic filter defines an upper passband, a lower passband, and a notch between the upper passband and the lower passband;
the lower passband defines an upper band edge, the upper band edge being below a low notch edge of the notch;
the upper passband defines a lower band edge, the lower band edge being above a high notch edge of the notch;
the acoustic filter has the low pass frequency response with a low pass corner frequency that is at or is below the low notch edge of the notch but above the upper band edge of the lower passband; and
the second filter has the high pass frequency response with a high pass corner frequency that is above the high notch edge of the notch but below the lower band edge of the upper passband.

16. The user element of claim 15, wherein:
the acoustic filter is configured to generate spurious modes above the lower band edge of the upper passband;
the low pass frequency response has a first depth between the low notch edge and the high notch edge that is at least as deep as a second depth of the notch;
the low pass frequency response is configured to filter the spurious modes above the low band edge of the upper passband; and
the high pass corner frequency of the second filter is below the lower band edge of the upper passband but above the high notch edge of the notch.

17. The user element of claim 12, wherein:
the first type of filter response is the high pass filter response and the second type of filter response is the low pass filter response.

18. The user element of claim 17, wherein:
the acoustic filter defines an upper passband, a lower passband, and a notch between the upper passband and the lower passband;
the upper passband defines an lower band edge, the lower band edge being above a high notch edge of the notch;
the lower passband defines a upper band edge, the upper band edge being below a low notch edge of the notch;
the acoustic filter has the high pass frequency response with a high pass corner frequency that is at or is above the high notch edge of the notch but below the lower band edge of the upper passband; and
the second filter has the low pass frequency response with a low pass corner frequency that is below the low notch edge of the notch but above the upper band edge of the upper passband.

19. The user element of claim 18, wherein:
the acoustic filter is configured to generate spurious modes below the upper band edge of the lower passband;
the high pass frequency response has a first depth between the low notch edge and the high notch edge that is at least as deep as a second depth of the notch;
the high pass frequency response is configured to filter the spurious modes below the high band edge of the lower passband; and
the low pass corner frequency of the second filter is above the upper band edge of the lower passband but below the low notch edge of the notch.

20. The user element of claim 12, wherein the acoustic filter is a surface acoustic wave (SAW) filter or a bulk acoustic wave (BAW) filter.
